(19) United States
(12) Patent Application Publication
(10) Pub. No.: US 2008/0190764 A1
(43) Pub. Date: Aug. 14, 2008

(54) Method of manufacturing aluminum and aluminum alloy sputtering targets

(76) Inventors: Shan Torng, Longtan Township (TW); Chune-Ching Young, Longtan Township (TW); Shih-Ying Chen, Taoyuan City (TW); Po-Chun Hsu, Sanchong City (TW); Chia-Hsiang Peng, Taichung (TW); Fan-Chun Tseng, Pingjhen City (TW); Ren-An Luo, Longtan Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/071,935

(22) Filed: Feb. 28, 2008

Related U.S. Application Data
(62) Division of application No. 11/411,757, filed on Apr. 27, 2006.

(30) Foreign Application Priority Data
Dec. 20, 2005 (TW) 094145170

(51) Int. Cl. C23C 14/14

(52) U.S. Cl. 204/298.13

(57) ABSTRACT

A manufacturing method of sputtering targets uses a direct-chill method to fabricate various aluminum and aluminum alloy ingots. Without the need of follow-up forging processes, the fabricated aluminum alloy ingots can be cut to attain aluminum and aluminum alloy sputtering targets. The method according to the present invention features the advantages of few process steps, high productivity, and high yield. In addition, the fabricated targets have small grains, fine precipitate phases, and homogeneous composition.

### RELATED APPLICATIONS

This application is a Divisional patent application of co-pending application Ser. No. 11/411,757, filed on 27 Apr. 2006. The entire disclosure of the prior application Ser. No. 11/411,757, from which an oath or declaration is supplied, is considered a part of the disclosure of the accompanying Divisional/Continuation application and is hereby incorporated by reference.

### FIELD OF THE INVENTION

The present invention relates to a manufacturing technology of aluminum and aluminum alloy targets used for thin-film sputtering in semiconductor and optoelectronic industries. By using a direct-chill casting method, aluminum and aluminum alloy targets suitable for semiconductor and optoelectronic industries can be manufactured.

### BACKGROUND OF THE INVENTION

Aluminum thin films have the characteristics of high reflectivity and low resistivity, thereby they are usually applied in manufacturing reflection layers of CD-ROMs, interconnection layers of semiconductors, and electrode layers of display devices. In general, apparatus for manufacturing aluminum alloy thin films is mainly by sputter processes. A sputter process uses plasma to bombard targets, so that the surface atoms of the target are scattered to escape the surface thereof and are deposited on a substrate. After processes of adhesion, adsorption, surface migration, and nucleation, a thin film is formed on the substrate. The quality of the thin film depends on sputter machines and sputtering parameters. In addition, it also depends significantly on the quality of the target used. The characteristics of targets include purity, grain size, density, and sizes of precipitates, which characteristics influence seriously on uniformity of sputtered thin films.

Generally, fabrication of metal targets mainly uses a casting method or a powder metallurgy method. The casting method melts and mixes component elements. Afterwards, the melt is dispensed into molds and quenched to form an ingot. Because there exists the problems of shrinkage voids, air voids, large grain sizes, and composition segregation in structures made by normal casting, the fabricated ingot has to be refined to improve its structure. For example, according to Taiwan patent number 117,131, after a target billet is cast, it is deformed by rolling or forging, and the coarse cast structure can be improved by recrystallization in terms of a hot treatment, and larger proeutectic phases can be refined and be distributed uniformly. In addition, according to U.S. Pat. No. 6,723,187, the ingot fabricated by casting is processed by hot forging and four to six passes of equal channel angular extrusion (ECAE). Besides, intermediate annealing is carried out between passes of ECAE such that recovery and recrystallization phenomena occur on the original cast structure, and grains can be refined gradually and precipitate phases can be refined and be distributed uniformly as well. Although this method can fabricate grains with sizes below 20 micrometers, the disadvantages thereof are complex and time-consuming of follow-up processes, and expensive process costs.

Furthermore, according to Taiwan patent number 541,350, by using vacuum induction melting (VIM) together with the double-V melting process of vacuum arc remelting (VAR), the problems of segregation, coarse inner grains, and deeper shrinkage voids caused by insufficient cooling inside of the ingot in the single-V (VIM) melting process can be improved. The process can be used for fabricating homogeneous and high-purity metal alloy targets such as aluminum, titanium, or copper alloy targets. Nevertheless, because the method needs to be operated in a high-vacuum environment, equipment investments for fabricating aluminum alloy targets is relatively costly. Besides, the method needs two passes of melting, which consequently lengthens production time.

Accordingly, the traditional casting processes of fabricating aluminum and aluminum alloy targets are relatively complicated. Up to now, there is no manufacturing method with a simple process and high productivity.

### SUMMARY

The purpose of the present invention is to provide a method for manufacturing high-quality aluminum alloy targets suitable for semiconductor and optoelectronic industries. The features of the present invention include that follow-up sintering, hot pressing, or forging and rolling processes are not needed, and that vacuum environments are not necessary for melting to cast aluminum alloy targets with fine grains, fine precipitate phases, and homogeneous structures. The process according to the present invention also features high yield and high productivity.

The manufacturing method of aluminum and aluminum alloy targets according to the present invention is a direct-chill casting method. The principle thereof is dispensing processed melt steadily into casting molds cooled by water. When the melt passes and contacts the surfaces of the molds, heat is brought away rapidly via heat conduction and the melt solidifies to form a surface solid-state thin shell. Then, said surface solid-state thin shell is flushed by a cooling spout to quench the inside thereof continuously, and thereby form a solid-state ingot. The ingot follows the casting platform and is moved with a constant speed until the predetermined casting length is achieved (vertical direct-chill casting). If a horizontal scheme is adopted, continuous production is possible. The casting process does not need to be operated in a vacuum environment as required by the double-V process. In addition, it is not necessary to carry out follow-up molding processes on the cast targets like traditional casting methods. Thereby, the manufacturing method according to the present invention is capable of fabricating aluminum alloy targets with a thin surface composition segregation layer as well as with a fine cast grain structure.

The present invention adopts a direct-chill casting method with appropriate pre-melt processes to fabricate pure metal aluminum, or aluminum alloy sputtering targets alloyed with at least one of elements chosen from the group consisting of copper, manganese, silicon, magnesium, zinc, titanium, scandium, zirconium, vanadium, chromium, iron, cobalt, lithium, silver, yttrium, hafnium, tantalum, and carbon. The grain sizes of fabricated targets are below 100 micrometers; the sizes of secondary precipitate phases are below 50 micrometers. Consequently, the method according to the present invention is suitable for mass-producing high-quality aluminum alloy targets for semiconductor and optoelectronic industries.

### BRIEF DESCRIPTION OF THE DRAWINGS

FIG. 1 is a lateral cross-sectional metallurgical microscopic photograph of an aluminum-silicon-magnesium alloy target fabricated by a direct-chill casting method according to the present invention;

FIG. 2 is another lateral cross-sectional metallurgical microscopic photograph of an aluminum-silicon-magnesium alloy target fabricated by a direct-chill casting method according to the present invention;

FIG. 3 is a lateral cross-sectional metallurgical microscopic photograph of an aluminum-titanium alloy target fabricated by a direct-chill casting method according to the present invention; and

FIG. 4 is another lateral cross-sectional metallurgical microscopic photograph of an aluminum-titanium alloy target fabricated by a direct-chill casting method according to the present invention.

### DETAILED DESCRIPTION

According to the present invention, embodiments of fabricating an aluminum-titanium alloy target and an aluminum-silicon-magnesium alloy target using a vertical direct-chill casting method are described as follows.

### Embodiment 1

A pure aluminum ingot with high purity is added into a graphite crucible with 500 kg capacity. After the aluminum ingot is melt completely by heating the crucible using heating wires, a pure magnesium ingot and an aluminum-silicon master alloy are added, and the temperature of the aluminum melt is raised above the liquidus temperature. After the raw materials are melting, the aluminum melt is dreg-removed, degassed, and held. Then, the aluminum melt is injected into a flooding tank system. When the melt flows past the flooding tank, it is degassed in situ and is filtered by a porous ceramic filtering board to reduce contents of hydrogen and miscellaneous non-metal articles in the aluminum melt. Besides, casting is carried out above the liquidus temperature, wherein the casting uses a 4-inch direct-chill mold with four mold cavities. After casting is completed, four aluminum-silicon-magnesium alloy sticks with a 3-meter length and a 4-inch diameter are attained. Afterwards, both ends of the sticks are cut by 10 centimeters (approximately 4 inches) and sputtering targets are thereby fabricated. The yield of production is above 90%.

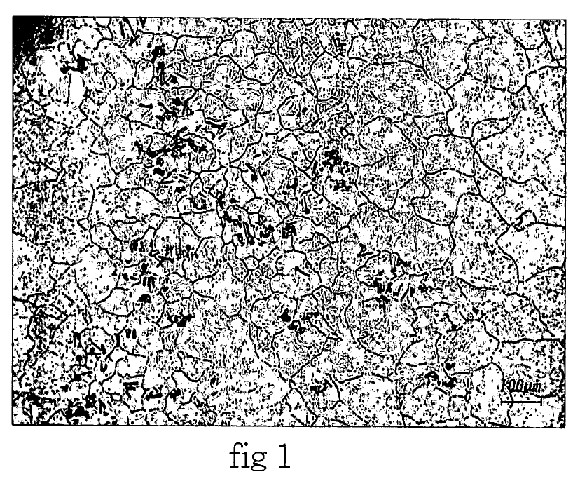

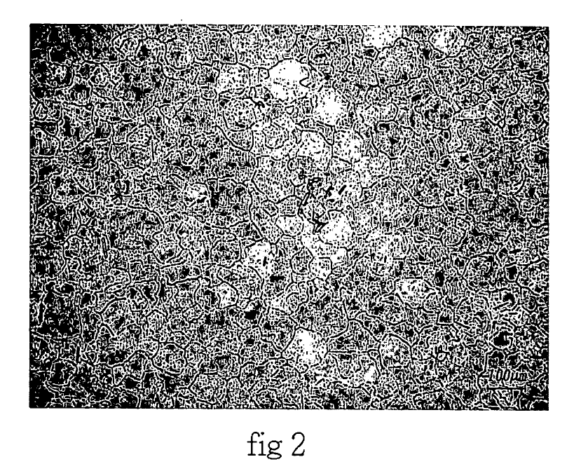

FIG. 1 and FIG. 2 are lateral cross-sectional metallurgical microscopic photographs of a fabricated target. As shown in the figure, after casting, the structure of the target is mainly cellular cast structure. The grain sizes thereof are below 100 micrometers, and there exists no other precipitate phases inside.

### Embodiment 2

A pure aluminum ingot with high purity is added into a graphite crucible with 500 kg capacity. After the aluminum ingot is melt completely by heating the crucible using heating wires, a pure titanium flake is added, and the temperature of the aluminum melt is raised above the liquidus temperature of the Al—Ti phase diagram to make the added titanium flake melt completely. Meanwhile, inert gas is introduced to prevent severe oxidation of the aluminum melt under high temperatures. After the raw materials are melting, the aluminum melt is dreg-removed, degassed, and held. Then, the aluminum melt is injected into a flooding tank system. When the melt flows past the flooding tank, it is degassed in situ and is filtered by a porous ceramic filtering board to reduce contents of hydrogen and miscellaneous non-metal articles in the aluminum melt. Besides, casting is carried out above the liquidus temperature of the Al—Ti phase diagram, wherein the casting uses a 4-inch direct-chill mold with four mold cavities. After casting is completed, four aluminum-titanium alloy sticks with a 3-meter length and a 4-inch diameter are attained. Afterwards, both ends of the sticks are cut by 10 centimeters (approximately 4 inches) and sputtering targets are thereby fabricated. The yield of production is above 90%.

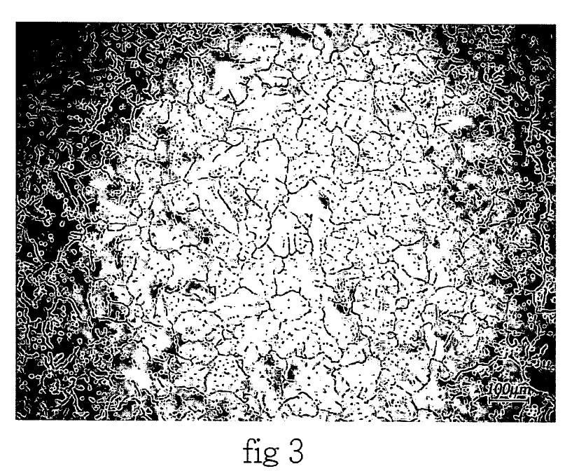

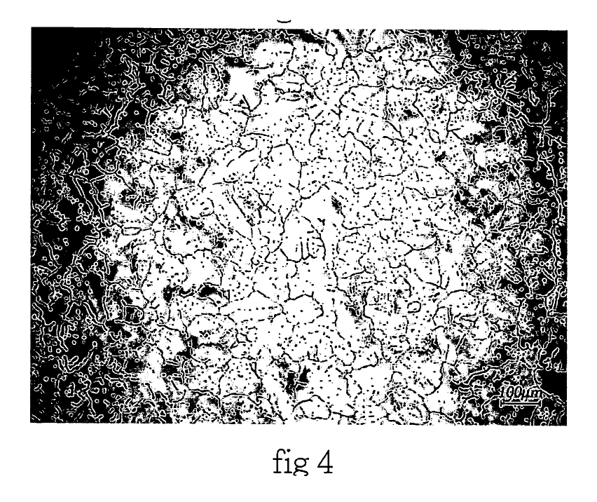

FIG. 3 and FIG. 4 are lateral cross-sectional metallurgical microscopic photographs of a fabricated target. As shown in the figure, after casting, the structure of the target is mainly uniaxial cellular cast structure. The grain sizes thereof are below 100 micrometers, and there exists a small amount of Al₃Ti precipitate phases inside with sizes mostly below 50 micrometers.

According to the embodiments described above, it shows that, without follow-up forging processes, the targets fabricated by the direct-chill casting method according to the present invention are fine in grains and in precipitate phases. The grain sizes thereof are below 100 micrometers, and the sizes of precipitate phases thereof are below 50 micrometers.

Accordingly, the present invention conforms to the legal requirements owing to its novelty, unobviousness, and utility. However, the foregoing description is only a preferred embodiment of the present invention, not used to limit the scope and range of the present invention. Those equivalent changes or modifications made according to the shape, structure, feature, or spirit described in the claims of the present invention are included in the appended claims of the present invention.

1. A sputtering target comprising:
direct-chill cast ingot formed of a pure metal aluminum, or aluminum alloy alloyed with at least one element chosen from the group consisting of: copper, manganese, silicon, magnesium, zinc, titanium, scandium, zirconium, vanadium, chromium, iron, cobalt, lithium, silver, yttrium, hafnium, tantalum, and carbon;
wherein the ingot is substantially free of hydrogen and non-metal content, and is formed with grain sizes below 100 micrometers, the ingot being homogeneous in structure, with precipitate phase sizes of less than 50 micrometers.
